(19) United States
(12) Patent Application Publication
(10) Pub. No.: US 2024/0322766 A1
(43) Pub. Date: Sep. 26, 2024

(54) 5G MMWAVE POWER AMPLIFIER CONTROL CIRCUITRY

(71) Applicant: Skyworks Solutions, Inc., Irvine, CA (US)

(72) Inventors: Florinel G. Balteanu, Irvine, CA (US); Saunak Sarkar, Irvine, CA (US); Manjunath Kareppagoudr, Corvallis, OR (US); Sruthi Venimadhavan, Irvine, CA (US); Yunyoung Choi, Irvine, CA (US)

(21) Appl. No.: 18/612,200

(22) Filed: Mar. 21, 2024

Related U.S. Application Data
(60) Provisional application No. 63/454,584, filed on Mar. 24, 2023.

(51) Int. Cl. H03F 3/21; H03F 1/56; H04B 1/40

(52) U.S. Cl. CPC H03F 3/211; H03F 1/56; H03F 2200/387; H03F 2200/451; H04B 1/40

(57) ABSTRACT

This application relates to an amplification circuit comprising: a power amplifier stage configured to receive a supply voltage and an RF signal to be amplified; a biasing circuit configured to receive an envelope signal produced from the RF signal and input a bias signal into the power amplifier, said bias signal varying based on the envelope signal such that the bias signal dynamically modulates an output impedance of the power amplifier based on the envelope signal; and an output stage configured to output an amplified RF signal generated by the power amplifier.

### INCORPORATION BY REFERENCE TO ANY PRIORITY APPLICATIONS

This application claims priority to U.S. Provisional Application No. 63/454,584, filed on Mar. 24, 2023 and titled “5G MMWAVE POWER AMPLIFIER CONTROL CIRCUITRY,” the disclosure of which is hereby incorporated by reference in its entirety for all purposes. Any and all applications for which a foreign or domestic priority claim is identified in the Application Data Sheet as filed with the present application are hereby incorporated by reference under 37 CFR 1.57.

### BACKGROUND

### Field

Embodiments of the present application relate to electronic systems, and in particular to power amplification systems for radio frequency (RF) electronics.

### Description of the Related Technology

Power amplifiers (PAs) are used in radio frequency (RF) communication systems to amplify RF signals for transmission via antennas. It is important to manage the power of RF signal transmissions to prolong battery life and/or provide a suitable transmit power level.

Examples of RF communication systems with one or more power amplifiers include, but are not limited to, mobile phones, tablets, base stations, network access points, customer-premises equipment (CPE), laptops, and wearable electronics. For example, in wireless devices that communicate using a cellular standard, a wireless local area network (WLAN) standard, and/or any other suitable communication standard, a power amplifier can be used for RF signal amplification. An RF signal can have a frequency in the range of about 30 kHz to 300 GHZ, such as in the range of about 410 MHz to about 7.125 GHz for fifth generation (5G) communications in frequency range 1 (FR1), and such as in the range of about 24.25 GHz to 71.0 GHz for 5G communications in frequency range 2 (FR2).

Dynamic supply modulation (DSM) techniques, for example envelope tracking (ET), are used with power amplifiers. In such techniques, the supplied power is modified based on the envelope of the input RF signal. This means that the power amplifier is supplied with a higher power only when needed for a larger input signal, and is supplied with a lower power for a smaller input signal, thus improving efficiency.

Dynamic load modulation (DLM) techniques are also used with power amplifiers. In such techniques, instead of modulating the supply voltage, the envelope of the input RF signal is used to modulate the output impedance of the power amplifier. The output impedance of the power amplifier is decreased as the RF envelope increases. Again this results in an increase in efficiency. Example of DLM techniques include varactor-based DLM, and current injection-based active load modulation (ALM), for example Chirex outphasing, Doherty PAs, and load modulated balanced amplifier (LMBA).

In either case, power amplifiers are typically supplied with a constant bias signal to keep the power amplifier in the operating region.

### SUMMARY

According to certain embodiments there is provided an amplification circuit comprising: a power amplifier stage configured to receive a supply voltage and an RF signal to be amplified; a biasing circuit configured to receive an envelope signal produced from the RF signal and input a bias signal into the power amplifier, said bias signal varying based on the envelope signal such that the bias signal dynamically modulates an output impedance of the power amplifier based on the envelope signal; and an output stage configured to output an amplified RF signal generated by the power amplifier.

In one example, the envelope signal is a time calibrated envelope signal.

In one example, the envelope signal is time calibrated such that the bias signal input into the power amplifier is time calibrated to within 3 ns of the envelope of the RF signal, preferably to within 2 ns of the envelope of the RF signal, more preferably to within Ins of the envelope of the RF signal, more preferably to within 0.5 ns of the envelope of the RF signal.

In one example, the envelope signal is a current signal that varies based on the envelope of the RF signal.

In one example, the bias circuit is configured to receive a constant bias signal, preferably a constant current signal.

In one example, the bias circuit comprises a differential amplifier.

In one example, a first input of the differential amplifier receives the envelope signal.

In one example, a second input of the differential amplifier is connected to a drain or collector terminal of a transistor in the power amplifier stage.

In one example, an output of the differential amplifier is connected to a gate or base terminal of a transistor in the power amplifier stage.

In one example, the supply voltage is a constant voltage signal.

In one example, the amplification circuit further comprises an envelope tracking driver configured to receive the envelope signal produced from the RF signal and to vary the supply voltage based on the envelope signal.

In one example, the envelope signal is a time calibrated envelope signal

In one example, an increase in the envelope signal produced from the RF signal causes an increase in the bias signal, and the increase in the bias signal causes a decrease in the output impedance of the power amplifier.

In one example, an increase in the envelope signal produced from the RF signal causes an increase in the bias signal, and the increase in the bias signal causes an increase in a load line of the power amplifier.

In one example, the amplification circuit further comprises an input stage configured to input the RF signal to be amplified into the power amplifier.

In one example, the RF signal has a modulation bandwidth greater than 1 MHZ, preferably greater than 10 MHz, more preferably greater than 20 MHz, more preferably greater than 60 MHz.

In one example, the RF signal is a 5G mmWave signal.

According to certain additional embodiments there is provided an amplification method comprising the steps of: receiving, by a power amplifier stage, a supply voltage and an RF signal to be amplified; inputting a bias signal into the power amplifier, said bias signal varying based on an envelope signal produced from the RF signal such that the bias signal dynamically modulates an output impedance of the power amplifier based on the envelope signal; and outputting an amplified RF signal generated by the power amplifier.

According to certain additional embodiments there is provided a wireless device comprising: a transceiver configured to generate an RF signal; a front-end module (FEM) in communication with the transceiver, the FEM including a packaging substrate configured to receive a plurality of components, and an amplification circuit comprising: a power amplifier stage configured to receive a supply voltage and an RF signal to be amplified; a biasing circuit configured to input a bias signal into the power amplifier, said bias signal varying based on an envelope signal produced from the RF signal such that the bias signal dynamically modulates an output impedance of the power amplifier based on the envelope signal; and an output stage configured to output an amplified RF signal generated by the power amplifier; and an antenna in communication with the FEM, the antenna configured to transit the output RF signal received from the amplification circuit.

Still other aspects, embodiments, and advantages of these exemplary aspects and embodiments are discussed in detail below. Embodiments and/or examples disclosed herein may be combined with other embodiments or examples in any manner consistent with at least one of the principles disclosed herein, and references to “an embodiment,” “some embodiments,” “an alternate embodiment,” “various embodiments,” “one embodiment” or the like are not necessarily mutually exclusive and are intended to indicate that a particular feature, structure, or characteristic described may be included in at least one embodiment. The appearances of such terms herein are not necessarily all referring to the same embodiment.

### BRIEF DESCRIPTION OF THE DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the disclosure. In the figures, each identical or nearly identical component that is illustrated in various figures is represented by a like numeral. For purposes of clarity, not every component may be labeled in every figure. In the figures:

FIG. 1 is a schematic diagram of one example of a communication network according to certain aspects of the present disclosure.

FIG. 2a is a schematic diagram of one example of a bias-based load modulation power amplifier system according to certain aspects of the present disclosure.

FIG. 2b is a schematic diagram of one example of a output impedance matching circuit according to certain aspects of the present disclosure.

FIG. 3 is a graph showing modulation of a load line in certain aspects of the present disclosure.

FIG. 4 is an example method of bias-based load modulation according to certain aspects of the present disclosure.

FIG. 5a is a graph of adjacent channel leakage ratio for signals with a number of different modulation bandwidths according to certain aspects of the present disclosure.

FIG. 5b is a schematic diagram of one example of a time calibrated bias-based load modulation power amplifier system according to certain aspects of the present disclosure.

FIG. 5c is a schematic diagram of one example of a time calibrated bias-based load modulation power amplifier system according to certain aspects of the present disclosure.

FIG. 6 is an example method of bias-based load modulation according to certain aspects of the present disclosure.

FIG. 7a is a schematic diagram of one example of a bias-based load modulation power amplifier system according to certain aspects of the present disclosure.

FIG. 7b is a graph showing modulation of a load line in certain aspects of the present disclosure.

FIG. 8 is a schematic diagram of one example of a bias-based load modulation power amplifier circuit according to certain aspects of the present disclosure.

FIG. 9 is a schematic diagram of one example of a bias-based load modulation power amplifier circuit according to certain aspects of the present disclosure.

FIG. 10 is a schematic diagram of one example of a bias-based load modulation power amplifier circuit according to certain aspects of the present disclosure.

FIG. 11 is a schematic diagram of one example of a circuit for generation of an envelope current signal according to certain aspects of the present disclosure.

FIG. 12 is a schematic diagram of one example of a dual input differential amplifier circuit included in the circuit of FIG. 11.

FIG. 13 is a schematic diagram of one example of a biasing circuit according to certain aspects of the present disclosure.

FIG. 14 is a schematic diagram of one example of a front-end module according to certain aspects of the present disclosure.

FIG. 15 is a schematic diagram of one example of a wireless device according to certain aspects of the present disclosure.

FIG. 16 is a schematic diagram of one example of a MIMO system according to certain aspects of the present disclosure.

### DETAILED DESCRIPTION

Aspects and embodiments described herein are directed to a power amplification systems, methods and circuitry for performing bias-based load modulation to increase the efficiency of a power amplifier.

It is to be appreciated that embodiments of the methods and apparatuses discussed herein are not limited in application to the details of construction and the arrangement of components set forth in the following description or illustrated in the accompanying drawings. The methods and apparatuses are capable of implementation in other embodiments and of being practiced or of being carried out in various ways. Examples of specific implementations are provided herein for illustrative purposes only and are not intended to be limiting. Also, the phraseology and terminology used herein is for the purpose of description and should not be regarded as limiting. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms.

The International Telecommunication Union (ITU) is a specialized agency of the United Nations (UN) responsible for global issues concerning information and communication technologies, including the shared global use of radio spectrum.

The 3rd Generation Partnership Project (3GPP) is a collaboration between groups of telecommunications standard bodies across the world, such as the Association of Radio Industries and Businesses (ARIB), the Telecommunications Technology Committee (TTC), the China Communications Standards Association (CCSA), the Alliance for Telecommunications Industry Solutions (ATIS), the Telecommunications Technology Association (TTA), the European Telecommunications Standards Institute (ETSI), and the Telecommunications Standards Development Society, India (TSDSI).

Working within the scope of the ITU, 3GPP develops and maintains technical specifications for a variety of mobile communication technologies, including, for example, second generation (2G) technology (for instance, Global System for Mobile Communications (GSM) and Enhanced Data Rates for GSM Evolution (EDGE)), third generation (3G) technology (for instance, Universal Mobile Telecommunications System (UMTS) and High Speed Packet Access (HSPA)), and fourth generation (4G) technology (for instance, Long Term Evolution (LTE) and LTE-Advanced).

The technical specifications controlled by 3GPP can be expanded and revised by specification releases, which can span multiple years and specify a breadth of new features and evolutions.

In one example, 3GPP introduced carrier aggregation (CA) for LTE in Release 10. Although initially introduced with two downlink carriers, 3GPP expanded carrier aggregation in Release 14 to include up to five downlink carriers and up to three uplink carriers. Other examples of new features and evolutions provided by 3GPP releases include, but are not limited to, License Assisted Access (LAA), enhanced LAA (eLAA), Narrowband Internet of things (NB-IOT), Vehicle-to-Everything (V2X), and High Power User Equipment (HPUE).

3GPP introduced Phase 1 of fifth generation (5G) technology in Release 15, and introduced Phase 2 of 5G technology in Release 16. Subsequent 3GPP releases will further evolve and expand 5G technology. 5G technology is also referred to herein as 5G New Radio (NR).

5G NR supports or plans to support a variety of features, such as communications over millimeter wave spectrum, beamforming capability, high spectral efficiency waveforms, low latency communications, multiple radio numerology, and/or non-orthogonal multiple access (NOMA). Although such RF functionalities offer flexibility to networks and enhance user data rates, supporting such features can pose a number of technical challenges.

The teachings herein are applicable to a wide variety of communication systems, including, but not limited to, communication systems using advanced cellular technologies, such as LTE-Advanced, LTE-Advanced Pro, and/or 5G NR.

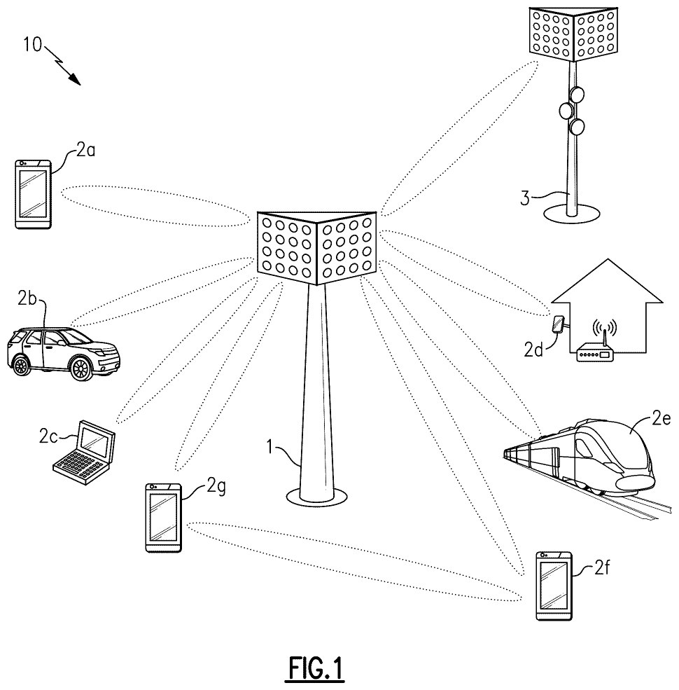

FIG. 1 is a schematic diagram of one example of a communication network 10. The communication network 10 includes a macro cell base station 1, a small cell base station 3, and various examples of user equipment (UE), including a first mobile device 2a, a wireless-connected car 2b, a laptop 2c, a stationary wireless device 2d, a wireless-connected train 2e, a second mobile device 2f, and a third mobile device 2g.

Although specific examples of base stations and user equipment are illustrated in FIG. 1, a communication network can include base stations and user equipment of a wide variety of types and/or numbers.

For instance, in the example shown, the communication network 10 includes the macro cell base station 1 and the small cell base station 3. The small cell base station 3 can operate with relatively lower power, shorter range, and/or with fewer concurrent users relative to the macro cell base station 1. The small cell base station 3 can also be referred to as a femtocell, a picocell, or a microcell. Although the communication network 10 is illustrated as including two base stations, the communication network 10 can be implemented to include more or fewer base stations and/or base stations of other types.

Although various examples of user equipment are shown, the teachings herein are applicable to a wide variety of user equipment, including, but not limited to, mobile phones, tablets, laptops, IoT devices, wearable electronics, customer premises equipment (CPE), wireless-connected vehicles, wireless relays, and/or a wide variety of other communication devices. Furthermore, user equipment includes not only currently available communication devices that operate in a cellular network, but also subsequently developed communication devices that will be readily implementable with the inventive systems, processes, methods, and devices as described and claimed herein.

The illustrated communication network 10 of FIG. 1 supports communications using a variety of cellular technologies, including, for example, 4G LTE and 5G NR. In certain implementations, the communication network 10 is further adapted to provide a wireless local area network (WLAN), such as WiFi. Although various examples of communication technologies have been provided, the communication network 10 can be adapted to support a wide variety of communication technologies.

Various communication links of the communication network 10 have been depicted in FIG. 1. The communication links can be duplexed in a wide variety of ways, including, for example, using frequency-division duplexing (FDD) and/or time-division duplexing (TDD). FDD is a type of radio frequency communications that uses different frequencies for transmitting and receiving signals. FDD can provide a number of advantages, such as high data rates and low latency. In contrast, TDD is a type of radio frequency communications that uses about the same frequency for transmitting and receiving signals, and in which transmit and receive communications are switched in time. TDD can provide a number of advantages, such as efficient use of spectrum and variable allocation of throughput between transmit and receive directions.

In certain implementations, user equipment can communicate with a base station using one or more of 4G LTE, 5G NR, and WiFi technologies. In certain implementations, enhanced license assisted access (eLAA) is used to aggregate one or more licensed frequency carriers (for instance, licensed 4G LTE and/or 5G NR frequencies), with one or more unlicensed carriers (for instance, unlicensed WiFi frequencies).

As shown in FIG. 1, the communication links include not only communication links between UE and base stations, but also UE to UE communications and base station to base station communications. For example, the communication network 10 can be implemented to support self-fronthaul and/or self-backhaul.

The communication links can operate over a wide variety of frequencies. In certain implementations, communications are supported using 5G NR technology over one or more frequency bands that are less than 6 Gigahertz (GHz) and/or over one or more frequency bands that are greater than 6 GHz. For example, the communication links can serve Frequency Range 1 (FR1), Frequency Range 2 (FR2), or a combination thereof.

For example, 5G NR can operate with different specifications across frequency bands for 5G, including with flexible numerology compared with fixed numerology for 4G. FR1 includes existing and new bands and corresponds to 450 MHZ-6 GHZ; sub-6 GHz bands with numerology subcarrier spacing of 15 kHz, 30 kHz and 60 kHz. Additionally, FR2 includes new bands and corresponds to millimeter wave frequencies of 24.25 GHZ-52.6 GHz with numerology subcarrier spacing of 60 kHz, 120 kHz and 240 kHz to be able to handle higher phase noise and Doppler effects (for instance, for train applications up to 500 km/h).

In certain implementations, a base station and/or user equipment communicates using beamforming. For example, beamforming can be used to focus signal strength to overcome path losses, such as high loss associated with communicating over high signal frequencies. In certain embodiments, user equipment, such as one or more mobile phones, communicate using beamforming on millimeter wave frequency bands in the range of 30 GHz to 300 GHz and/or upper centimeter wave frequencies in the range of 6 GHz to 30 GHZ, or more particularly, 24 GHZ to 30 GHz. In one embodiment, one or more of the mobile devices support a HPUE power class specification.

Different users of the communication network 10 can share available network resources, such as available frequency spectrum, in a wide variety of ways.

In one example, frequency division multiple access (FDMA) is used to divide a frequency band into multiple frequency carriers. Additionally, one or more carriers are allocated to a particular user. Examples of FDMA include, but are not limited to, single carrier FDMA (SC-FDMA) and orthogonal FDMA (OFDMA). OFDMA is a multicarrier technology that subdivides the available bandwidth into multiple mutually orthogonal narrowband subcarriers, which can be separately assigned to different users.

Other examples of shared access include, but are not limited to, time division multiple access (TDMA) in which a user is allocated particular time slots for using a frequency resource, code division multiple access (CDMA) in which a frequency resource is shared amongst different users by assigning each user a unique code, space-divisional multiple access (SDMA) in which beamforming is used to provide shared access by spatial division, and non-orthogonal multiple access (NOMA) in which the power domain is used for multiple access. For example, NOMA can be used to serve multiple users at the same frequency, time, and/or code, but with different power levels.

Enhanced mobile broadband (cMBB) refers to technology for growing system capacity of LTE networks. For example, cMBB can refer to communications with a peak data rate of at least 10 Gbps and a minimum of 100 Mbps for each user. Ultra-reliable low latency communications (uRLLC) refers to technology for communication with very low latency, for instance, less than 2 milliseconds. uRLLC can be used for mission-critical communications such as for autonomous driving and/or remote surgery applications. Massive machine-type communications (mMTC) refers to low cost and low data rate communications associated with wireless connections to everyday objects, such as those associated with Internet of Things (IoT) applications.

The communication network 10 of FIG. 1 can be used to support a wide variety of advanced communication features, including, but not limited to, eMBB, uRLLC, and/or mMTC.

### Bias-Based PA Load Modulation

Modern communication devices include front-end modules which contain one or more power amplifiers, for amplifying an RF signal to be transmitted. The front-end module may communicate using 5G technologies. In 5G, methods for increasing the data rate include the use of millimeter wave (mmWave) FR2 frequency bands, as well as the use of several antennas, i.e. multiple input multiple output (MIMO).

Both FR1 and mmWave FR2 frequency bands are examples of signals with a high modulation bandwidth, i.e. above about 1 MHz. The bias-based load modulation described herein is particularly suited for RF signals with high modulation bandwidths, using a simple system configuration from size and cost perspective.

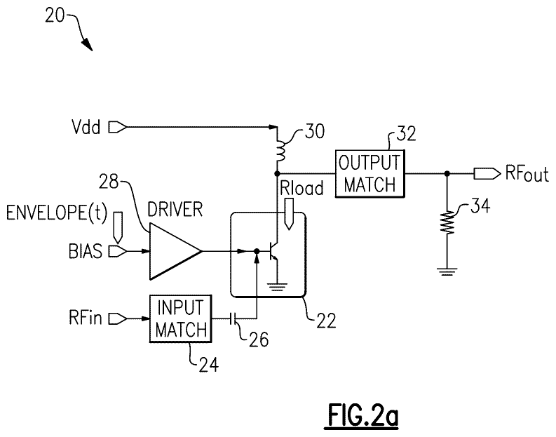

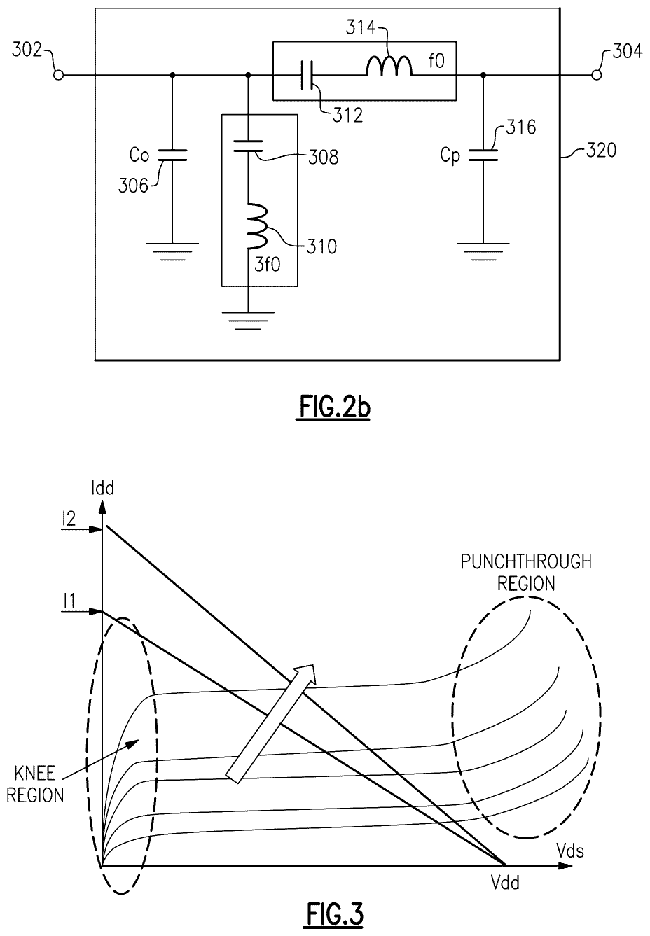

FIG. 2a shows a bias-based load modulation power amplifier system 20 according to an embodiment of the present disclosure. The power amplifier system 20 includes a power amplifier (PA) 22. The power amplifier system 20 further includes an input impedance matching circuit 24, a DC capacitor 26, a driver 28, an inductor 30, an output impedance matching circuit 32, and an output resistor 34.

The illustrated power amplifier 22 includes a bipolar transistor having an emitter, a base, and a collector. As shown in FIG. 2a, the emitter of the bipolar transistor is electrically connected to a power low supply voltage, which can be, for example, a ground supply. Additionally, an RF signal to be amplified (RFin) is provided to the base of the bipolar transistor, and the bipolar transistor amplifies the RF signal to generate an amplified RF signal (RFout) at the collector. The bipolar transistor can be any suitable device. In one implementation, the bipolar transistor is a heterojunction bipolar transistor (HBT).

Although FIG. 2a illustrates one implementation of the power amplifier 22, skilled artisans will appreciate that the teachings described herein can be applied to a variety of power amplifier structures, such as multi-stage power amplifiers and power amplifiers employing other transistor structures. For example, in some implementations the bipolar transistor 1129 can be omitted in favor of employing a field-effect transistor (FET), such as a silicon FET, a gallium arsenide (GaAs) high electron mobility transistor (HEMT), a laterally diffused metal oxide semiconductor (LDMOS) transistor, or MOSFETs.

Various different PA topologies may be used, and the PA can be implemented in a number of ways. For example, one amplifying transistor (as shown in FIG. 2a), or a plurality of amplifier transistors may be used in some embodiments. In some embodiments, a PA having a plurality of amplifying transistors arranged in stages may be used, with a first stage configured as, for example, a driver stage, and a second stage configured as an output stage. In some embodiments, a PA can be implemented in a cascode configuration. An input RF signal (RF_in) can be provided to a base of the first amplifying transistor operated as a common emitter device. The output of the first amplifying transistor can be provided through its collector and be provided to an emitter of the second amplifying transistor operated as a common base device. The output of the second amplifying transistor can be provided through its collector so as to yield an amplified output RF signal (RF_out) of the PA.

The RF signal to be amplified (RFin) is input into the PA 22 via the input impedance matching circuit 24 and capacitor 26. The capacitor 26 may act as a DC blocking capacitor, to prevent a DC signal passing to the PA 22.

The inductor 30 can be included to provide the PA 22 with the power amplifier supply voltage Vdd, while choking or blocking high frequency RF signal components. The inductor 30 can include a first end electrically connected to the supply voltage Vdd, and a second end electrically connected to the collector of the bipolar transistor of the PA 22. In the present embodiment, the power amplifier supply voltage Vdd may be a constant supply voltage.

The output impedance matching circuit 32 serves to terminate the output of the PA 22, which can aid in increasing power transfer and/or reducing reflections of the amplified RF signal generated by the power amplifier 22. In certain implementations, the output impedance matching circuit 32 further operates to provide harmonic termination and/or to control a load line impedance of the power amplifier 32. The output resistor 34 may be connected between the output of the output impedance matching circuit 32 and ground. In some embodiments, the output resistor represents the load for PA and is not a physical resistor. Such load is provided by an antenna in most cases.

An example output impedance matching circuit 32 in one embodiment of the present disclosure is shown in FIG. 2b. The output impedance matching circuit 300 of FIG. 2b is for a Class E power amplifier. The output impedance matching circuit 300 includes an input 302 and an output 304. A first capacitor 306 is connected between the input 302 and ground. A second capacitor 308 and a first inductor 310 are connected in series between the input 302 and ground. A third capacitor 312 and a second inductor 314 are connected in series between the input 302 an the output 304, with the first and second capacitors 306,308 being connected to a point between the input 203 and the third capacitor 312. A fourth capacitor 316 is connected between the output 304 and ground.

In general it is to be understood that various different output impedance matching circuits and various different classes of power amplifier may be used.

Returning to FIG. 2a, as well as the RFin signal, a bias signal is input into the PA 22, specifically into the base of the bipolar transistor of FIG. 2a. The bias signal is generated based on an envelope signal, ENVELOPE(t), produced from the RF signal that indicates an envelope of the RF signal. In this way, the PA 22 is biased based on the envelope of the RF signal to be amplified. This enables bias-based load modulation, as will be described in more detail below.

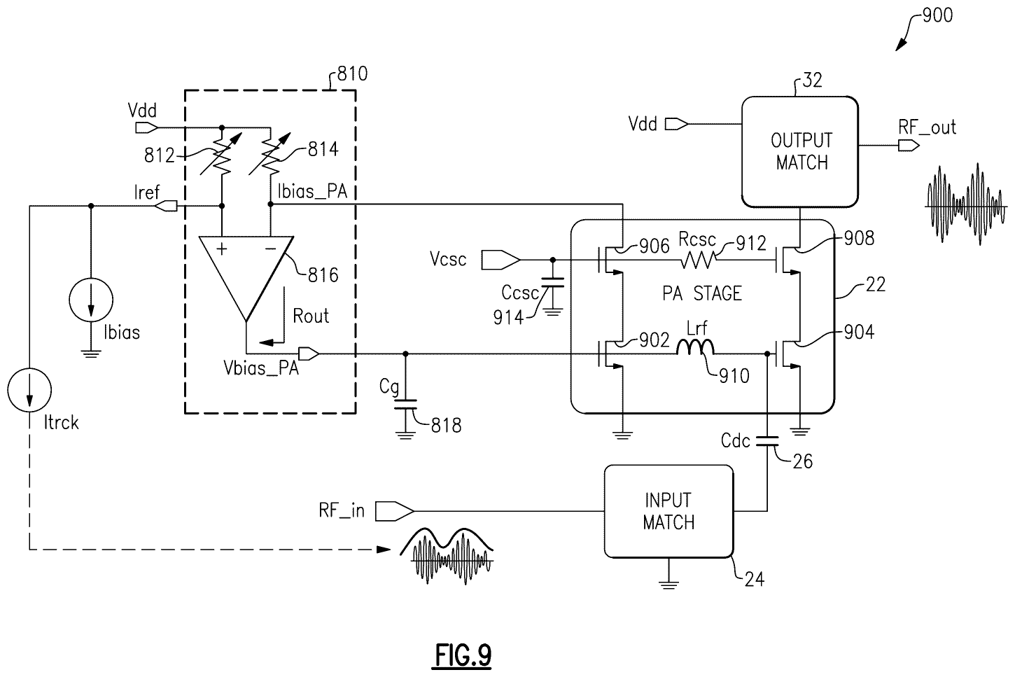

The bias signal may be formed by a combination of the envelope signal with a constant current or voltage signal in some embodiments. The bias signal is input into the PA 22 via the driver 28. Details of biasing circuits that may be used as the driver 28 will be described later with respect to FIGS. 8 to 10 (e.g. see biasing circuit 810).

The output impedance of the PA 22 is marked as Rload in FIG. 2a. Rload is the impedance seen by the PA 22 at the output. Rload is dependent on how much current the transistor allows to flow, i.e. the signal at the base/gate of the transition of the PA 22. Reducing the voltage at the base/gate of the transistor increases Rload, and vice versa. In the present embodiment, the envelope signal is used to generate the bias signal input at the base/gate of the transistor. Therefore when the envelope signal is larger the transistor allows more current to flow, thus reducing Rload, and vice versa. In this way, Rload is made inversely proportional to the envelope signal such that the power amplifier system 20 performs dynamic load modulation of the PA 22, due to the bias signal varying based on the envelope signal. The efficiency of the PA 22 is therefore increased.

In this way, the power amplifier system 20 of FIG. 2a performs load modulation in a novel way. Instead of modulating the load at the PA output, as done in conventional DLM, Rload is modulated through the bias signal following the envelope signal.

This load modulation can be understood using load line analysis. For example, the graph of FIG. 3 shows how the envelope-based bias signal modulates the load line of the PA in the example embodiment of FIG. 2a. As can be seen in FIG. 3, the lower load line on the graph (intersecting the y axis at 11) is the load line when an initial bias signal is input into the PA 22. When the bias signal increases, due to an increase in the envelope of the RF signal, Rload decreases and the gradient of the load line increases, thus moving the load line upwards as shown by the arrow in FIG. 3 and the upper load line on the graph (intersecting the y axis at 12). The bias signal therefore dynamically modulates the load line based on the envelope signal. When the envelope signal is larger the load line moves upwards on the graph, and when the envelope signal is smaller the load line moves downwards on the graph, thus improving the efficiency of the power amplifier 22.

It should be noted that for small signal the output impedance Rload is approximately proportional to Vds/Idd (where Vds is the drain-source (or collector-emitter) voltage of the amplifying transistor, and Idd is the drain current), and therefore the gradient of the load line is 1/Rload. For larger signals the exact value of Rload is dependent of the transistor conduction (Vds/Idc), and has to be determined by load pull measurements. In either case, increasing the bias signal decreases the value of Rload, and therefore makes the gradient of the load line steeper.

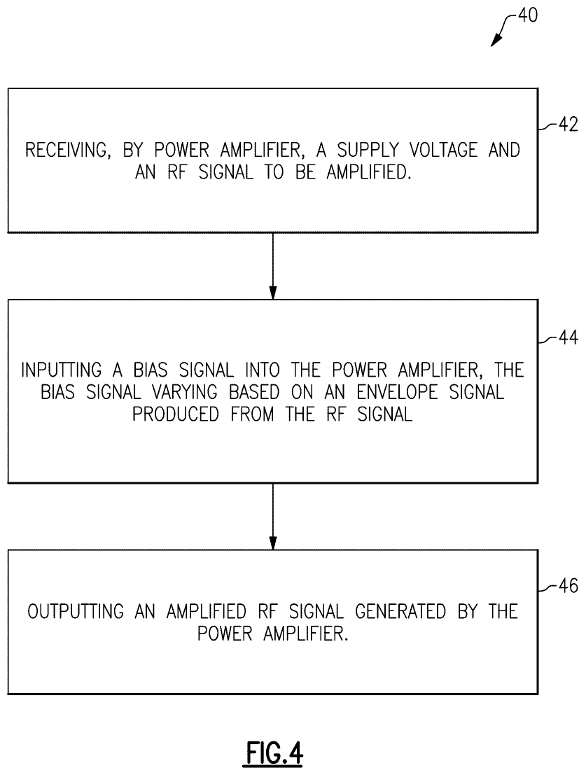

FIG. 4 shows a bias-based PA load modulation method 40 according to an embodiment of the present disclosure.

In step 42, the power amplifier 22 stage receives a supply voltage and an RF signal to be amplified.

In step 44, a bias signal is input into the power amplifier 22. As described above, the bias signal varies based on an envelope signal ENVELOPE(t) produced from the RF signal. The bias signal therefore dynamically modulates an output impedance of the power amplifier 22 based on the envelope signal.

In step 46 an amplified RF signal generated by the power amplifier is outputted.

Performing dynamic load modulation via the bias signal has a number of advantages over known DLM techniques. Firstly, RF losses are reduced compared with varactor-based load modulation, such as output match varactor load modulators where the varactor voltage is used to change the load line. Additionally, the bias-based load modulation has an increased dynamic range (for example, >12 dB) compared with known output match load modulators. Lastly, the bias-based load modulation reduces the slew rate (SR) requirements for the envelope tracking driver (i.e. driver 28 in the present embodiment); this is because as well as the RF gain from the PA 22, the driver 28 also introduces some baseband gain.

### Time Calibration

In some embodiments, the envelope signal ENVELOPE(t) may be a time calibrated signal. In particular, when the RF signal to be amplified (RFin) has a high modulation bandwidth (above about 1 MHz), such as FR1 or mmWave FR2 signals, time delay is important to enable successful dynamic load modulation via the bias signal. Previous attempts to modify a bias signal for a power amplifier have been made for low modulation bandwidth applications only, which do not require precise time calibration. Such attempts have a low frequency bias signal (e.g. due to filtering) which is not delayed calibrated, and therefore will not work for high bandwidth modulation cases due to the time delay introduced. Further previous attempts involve modifying the supply voltage using envelope tracking, whereas in the bias-based PA load modulation of FIG. 2a the supply voltage Vdd may be kept constant.

In typical envelope tracking systems, the intermodulation distortion (IMD) introduced by a delay mismatch between the envelope tracking signal and the RFin signal is given by the following equation:

$$I M {D}_{l , r} = 2 π {B}_{RF}^{2} {Δ}_{τ}^{2}$$

where B_{RF} is the modulation bandwidth of the RF signal and Δτ is the delay mismatch. The minimum between the left and right intermodulation distortion determines the adjacent channel leakage ratio (ACLR) of the enveloping tracking PA:

$$A C L R = min ( I M {D}_{l , r} ) + k$$

where k is a correction factor determined by the RF signal.

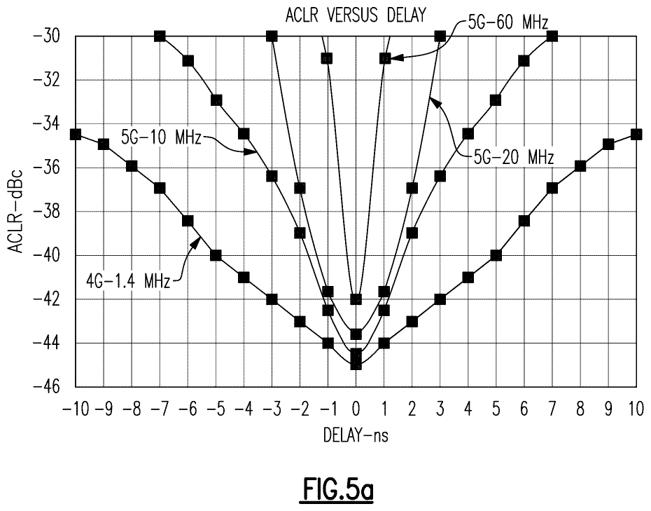

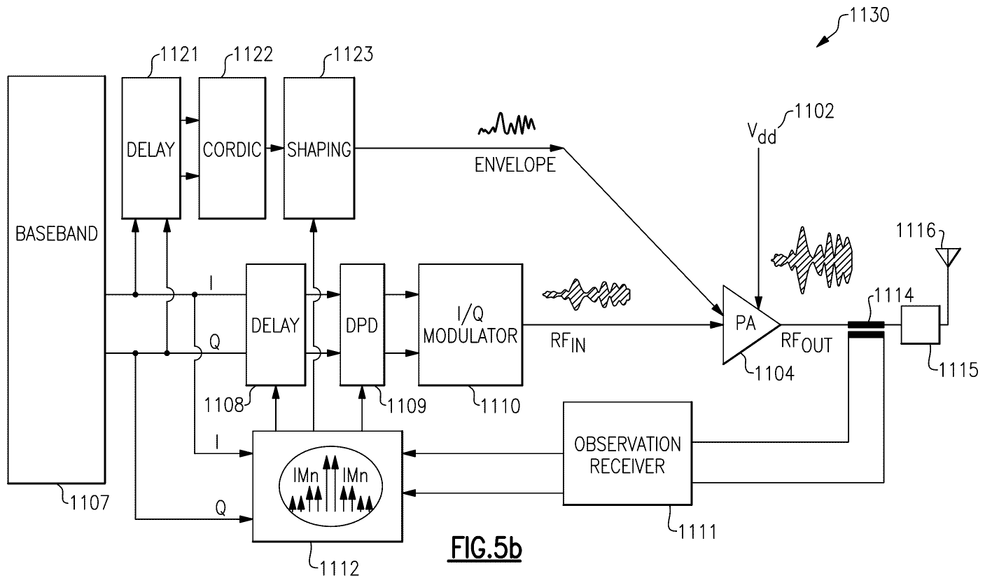

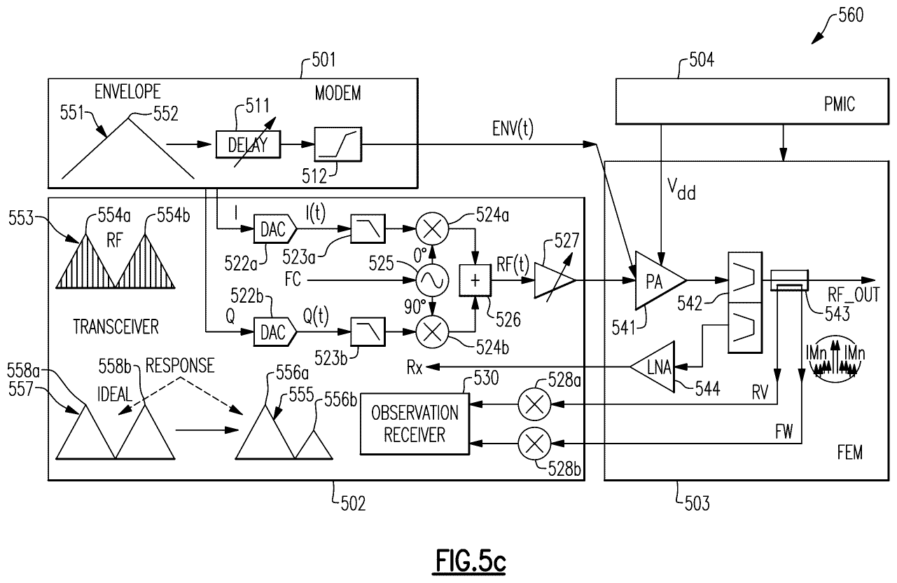

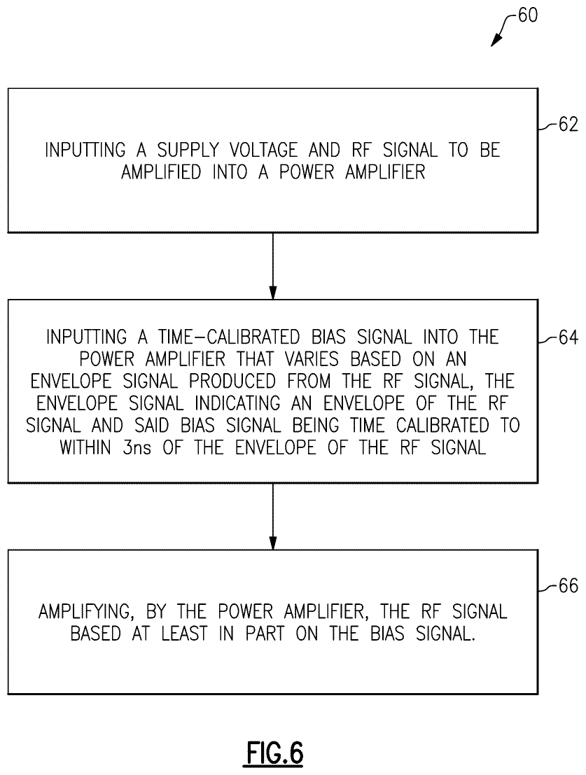

FIG. 5a shows a graph of ACLR against the time delay Δτ for signals with a number of different modulation bandwidths. In general, ACLR should be lower than-38 dBc. As can be seen from FIG. 5a, a delay of less than 3 ns is therefore required for signals with a modulation bandwidth above 10 MHz, and a delay of less than 2 ns is required for signals with a modulation bandwidth above 20 MHZ.

Further, 5G signals can have modulation bandwidths up to 100 MHz or more in some new 5G applications where carrier aggregation is involved. In such cases, from FIG. 5a it can be seen that the bias signal has to be delay calibrated within a precision of 0.5 ns or less.

Therefore, in some embodiments the envelope signal ENVELOPE(t) may be time calibrated, such that when the bias signal is input into the power amplifier there is a time delay of less than 3 ns between the bias signal and the envelope of input RF signal (RFin). In preferred embodiments, with higher modulation bandwidths, the time delay between the bias signal and the envelope of the RF signal may be within 2 ns, preferably within Ins, more preferably within 0.5 ns. Such time calibration allows generalization of the bias-based load modulation for all 4G and 5G modulation bandwidths, as well as providing the most optimal dynamic load modulation performance.

Various methods and configurations may be used to perform the time calibration between the envelope signal ENVELOPE(t) and the RF signal input into the PA, which in turn causes time calibration of the bias signal. For example, methods and configurations as described in U.S. Pat. No. 11,165,514 B2 may be used, which is hereby incorporated by reference in its entirety.

FIG. 5b shows one example embodiment of a bias-based load modulation power amplifier system 1130 in which the bias signal is time calibrated.

The system 1130 includes a power amplifier 1104 into which a constant supply voltage (Vdd) 1102 is input. The system further includes a baseband processor 1107, a signal delay circuit 1108, a digital pre-distortion (DPD) circuit 1109, an I/Q modulator 1110, an observation receiver 1111, an intermodulation detection circuit 1112, a directional coupler 1114, a duplexing and switching circuit 1115, an antenna 1116, an envelope delay circuit 1121, a coordinate rotation digital computation (CORDIC) circuit 1122, and a shaping circuit 1123.

The baseband processor 1107 operates to generate an I signal and a Q signal, which correspond to signal components of a sinusoidal wave or signal of a desired amplitude, frequency, and phase. For example, the I signal can be used to represent an in-phase component of the sinusoidal wave and the Q signal can be used to represent a quadrature-phase component of the sinusoidal wave, which can be an equivalent representation of the sinusoidal wave. In certain implementations, the I and Q signals are provided to the I/Q modulator 1110 in a digital format. The baseband processor 1107 can be any suitable processor configured to process a baseband signal. For instance, the baseband processor 1107 can include a digital signal processor, a microprocessor, a programmable core, or any combination thereof.

The signal delay circuit 1108 provides adjustable delay to the I and Q signals to aid in controlling relative alignment between the envelope signal and the RF signal RFIN. The amount of delay provided by the signal delay circuit 1108 is controlled based on amount of intermodulation detected by the intermodulation detection circuit 1112.

The DPD circuit 1109 operates to provide digital shaping to the delayed I and Q signals from the signal delay circuit 1108 to generate digitally pre-distorted I and Q signals. In the illustrated embodiment, the pre-distortion provided by the DPD circuit 1109 is controlled based on amount of intermodulation detected by the intermodulation detection circuit 1112. The DPD circuit 1109 serves to reduce a distortion of the power amplifier 1104 and/or to increase the efficiency of the power amplifier 1104.

The I/Q modulator 1110 receives the digitally pre-distorted I and Q signals, which are processed to generate an RF signal RFIN. For example, the I/Q modulator 1110 can include DACs configured to convert the digitally pre-distorted I and Q signals into an analog format, mixers for upconverting the analog I and Q signals to radio frequency, and a signal combiner for combining the upconverted I and Q signals into an RF signal suitable for amplification by the power amplifier 1104. In certain implementations, the I/Q modulator 1110 can include one or more filters configured to filter frequency content of signals processed therein.

The envelope delay circuit 1121 delays the I and Q signals from the baseband processor 1107. Additionally, the CORDIC circuit 1122 processes the delayed I and Q signals to generate a digital envelope signal representing an envelope of the RF signal RFIN. Although FIG. 5b illustrates an implementation using the CORDIC circuit 1122, an envelope signal can be obtained in other ways.

The shaping circuit 1123 operates to shape the digital envelope signal to enhance the performance of the system 1130. In certain implementations, the shaping circuit 1123 includes a shaping table that maps each level of the digital envelope signal to a corresponding shaped envelope signal level. Envelope shaping can aid in controlling linearity, distortion, and/or efficiency of the power amplifier 1104.

With continuing reference to FIG. 5b, the power amplifier 1104 receives the envelope signal from the shaping circuit 1123 as the bias signal, such that the bias signal input into the power amplifier 1104 changes in relation to the envelope of the RF signal RFIN. The power amplifier 1104 also receives the RF signal RFIN from the I/Q modulator 1110, and provides an amplified RF signal RFOUT to the antenna 1116, through the duplexing and switching circuit 1115 in this example.

The directional coupler 1114 is positioned between the output of the power amplifier 1104 and the input of the duplexing and switching circuit 1115, thereby allowing a measurement of output power of the power amplifier 1104 that does not include insertion loss of the duplexing and switching circuit 1115. The sensed output signal from the directional coupler 1114 is provided to the observation receiver 1111, which can include mixers for down converting I and Q signal components of the sensed output signal, and DACs for generating I and Q observation signals from the downconverted signals.

The intermodulation detection circuit 1112 determines an intermodulation product between the I and Q observation signals and the I and Q signals from the baseband processor 1107. Additionally, the intermodulation detection circuit 1112 controls the pre-distortion provided by the DPD circuit 1109 and a delay of the signal delay circuit 1108 to control relative alignment between the envelope signal and the RF signal RFIN. In certain implementations, the intermodulation detection circuit 1112 also serves to control shaping provided by the shaping circuit 1123.

By including a feedback path from the output of the power amplifier 1104 and baseband, the I and Q signals can be dynamically adjusted to optimize the operation of the system 1130. For example, configuring the system 1130 in this manner can aid in providing power control, compensating for transmitter impairments, and/or in performing DPD.

Further, the feedback path allows for the envelope signal, and thus to bias signal, to be time calibrated to allow bias-based load modulation for all modulation bandwidths. In the embodiment of FIG. 5b, the time calibration is performed in the digital domain via the observation receiver 1111, and therefore the system 1130 provides a fully digital transmitter (i.e. without the analog envelope tracking circuitry described in U.S. Pat. No. 11,165,514 B2).

Although illustrated as a single stage, the power amplifier 1104 can include one or more stages. Furthermore, the teachings herein are applicable to communication systems including multiple power amplifiers.

FIG. 5c shows another example embodiment of a bias-based load modulation power amplifier system 560 in which the bias signal is time calibrated

In the embodiment of FIG. 5c, calibration is performed by providing an envelope signal with a peak along an envelope path, and by providing an RF signal with a first peak and a second peak to a power amplifier along an RF signal path. Additionally, an output of the power amplifier is observed to generate an observation signal using an observation receiver. The observation signal includes a first peak and a second peak corresponding to the first peak and the second peak of the RF signal, and a delay between the envelope signal and the RF signal is controlled based on relative size of the peaks of the observation signal to one another.

In certain implementations, the delay is controlled such that the peaks in the observation signal are of about equal size to one another. Additionally, the delay can be incremented or decremented until alignment is achieved to within 3 ns or less, for example. Thus, an accurate and a flexible mechanism is provided for aligning an envelope signal to an RF signal.

The system 560 of FIG. 5c includes a baseband modem 501, a transceiver 502, a front-end module 503, and a power management integrated circuit (PMIC) 504.

In the illustrated embodiment, the baseband modem 501 includes a controllable delay circuit 511, and a shaping circuit 1123. The baseband modem 501 operates to generate an in-phase (I) signal and a quadrature-phase (Q) signal along with an envelope signal Env(t) indicating the envelope of the RF signal represented by the I signal and the Q signal. The controllable delay circuit 511 controls a delay of the envelope signal Env(t).

With continuing reference to FIG. 5c, the transceiver 502 includes an I-path digital-to-analog converter (DAC) 522a, a Q-path DAC 522b, an I-path baseband filter 523a, a Q-path baseband filter 523b, an I-path mixer 524b, a Q-path mixer 524b, a local oscillator 525, a combiner 526, a controllable driver 527, a first observation mixer 528a, a second observation mixer 528b, and an observation receiver 530. The transceiver 502 processes the I signal and the Q signal to generate an RF signal RF(t) that is amplified by the controllable driver 527 and thereafter provided to the front-end module 503.

The front-end module 503 includes a power amplifier 541, a duplexer 542, a directional coupler 543, a low noise amplifier (LNA) 544. The power amplifier 541 amplifies the RF signal from the transceiver 502 and provides an RF output signal RF_OUT by way of the duplexer 542 and directional coupler 543. The RF output signal RF_OUT is provided to an antenna (not shown in FIG. 5c) for transmission.

The power amplifier the power amplifier 541 receives a constant supply voltage Vdd from the PMIC 504. Further, the power amplifier 541 receives the envelope signal Env(t) from the baseband modem as the bias signal, such that the bias signal input into the power amplifier 541 changes in relation to the envelope of the input RF signal.

With continuing reference to FIG. 5c, the directional coupler 543 senses a reverse wave (RV) and a forward wave (FW), which are downconverted by the first observation mixer 528a and the second observation mixer 528b, respectively, and subsequently processed by the observation receiver 530.

The delay of the controllable delay circuit 511 controls a relative delay or time difference between the envelope signal Env(t) and the RF signal RF(t). Thus, the delay of the controllable delay circuit 511 can be set to a value for aligning the RF signal and the envelope-based bias signal at the power amplifier 541.

In the illustrated embodiment, the baseband modem 501 generates an envelope signal 551 by way of an envelope path to bias of the power amplifier 541. The envelope signal 551 includes a peak 552 and has a relatively low bandwidth. In one example, during calibration, the envelope signal 551 has a bandwidth of less than 1 MHz. Additionally, the baseband modem provides an RF signal 553 having a first peak 554a and a second peak 554b to the amplifier 541 by way of an RF signal path.

With continuing reference to FIG. 5c, the observation receiver 530 captures an observation signal 555 from an output of the power amplifier 541 by way of an observation path. The observation signal 555 includes a first peak 556a and a second peak 556b.

In certain implementations, the delay of the controllable delay circuit 511 is adjusted until the first peak 556a and the second peak 556b of the observation signal 555 are substantially equal, corresponding to an ideal signal 557 having a first peak 558a and a second peak 558b that are about equal to one another. Again, in the embodiment of FIG. 5c, the time calibration is performed in the digital domain via the observation receiver 530.

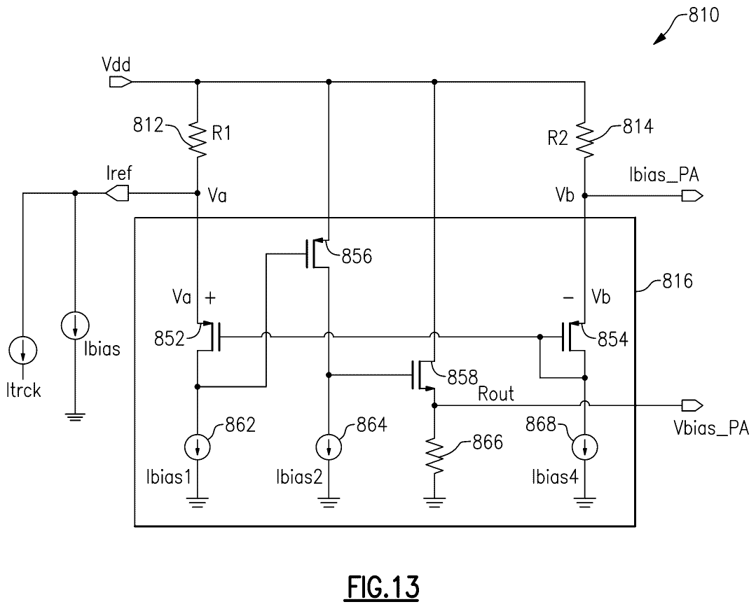

In each of the embodiments of FIGS. 5b and 5c, the envelope signal is input into the power amplifier as a bias signal. Exemplary circuitry for inputting the envelope signal as the bias signal will be described later in relation to FIGS. 8 and 13.

FIG. 6 shows a bias-based PA load modulation method 60 according to an embodiment of the present disclosure.

In step 62, a supply voltage is input into a power amplifier (e.g. the power amplifier 22, power amplifier 1104, or power amplifier 541).

In step 64, a time-calibrated bias signal is input into the power amplifier. The bias signal varies based on an envelope signal produced from the RF signal, the envelope signal indicating an envelope of the RF signal. The bias signal is time calibrated to within 3 ns of the envelope of the RF signal.

In step 66, the power amplifier amplifies the RF signal based at least in part on the bias signal.

The method of FIG. 6 allows generalization of the bias-based load modulation for all 4G and 5G modulation bandwidths, as well as providing the most optimal dynamic load modulation performance.

### Two-Way Envelope Tracking (ET) Modulator

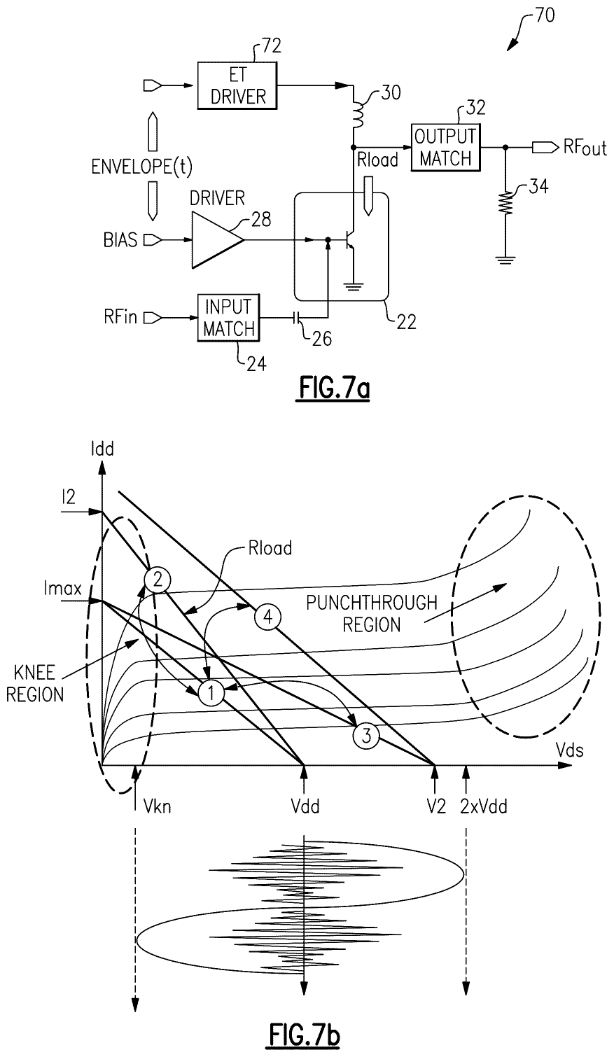

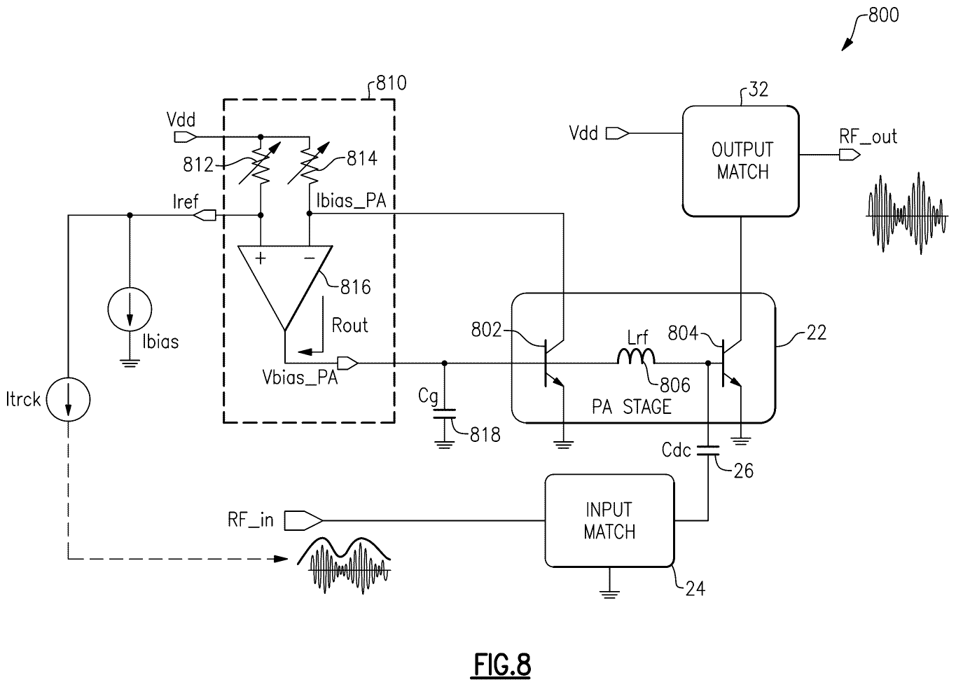

FIG. 7a shows a bias-based load modulation power amplifier system 70 according to another embodiment of the present disclosure. The power amplifier system 70 is similar to the power amplifier system 20 of FIG. 2a, in that it includes a power amplifier (PA) 22, an input impedance matching circuit 24, a capacitor 26, a driver 28, an inductor 30, an output impedance matching circuit 32, and an output resistor 34.

The bias-based load modulation power amplifier system 70 differs from that of FIG. 2a in that the power amplifier 22 is not supplied with a constant supply voltage. Instead, the power amplifier system 70 includes an Envelope Tracking (ET) driver 72 that provides a supply voltage to the PA 22 that varies based on the envelope of the input RF signal RFin. In particular, in the envelope signal ENVELOPE(t) is input into the ET driver 72, which outputs to the PA 22 (via the inductor 30) a supply voltage which varies based on ENVELOPE(t). The supply voltage may be made directly proportionally to the envelope signal ENVELOPE(t) in some embodiments.

In this way, the power amplifier system 70 may be described as a “two-way ET modulator”, as both the bias signal and the supply voltage are modulated based on the envelope of the RF signal. The envelope-based supply voltage causes dynamic supply modulation (DSM) to occur, as well as the dynamic load modulation (DLM) caused by the envelope-based bias signal. Various envelope tracking (ET) configurations may be used to perform this DSM, as would be understood by the skilled person.

Put another way, the load line for the power amplifier is modulated by the varying supply voltage based on the envelope signal, with a higher supply power increasing the load line (i.e. shifting the load line upwards whilst maintaining a constant gradient). This is illustrated in the graph of FIG. 7b, which shows how the envelope-based bias signal and envelope-based supply voltage together modulate the load line of the PA in the example embodiment of FIG. 7a.

As can be seen in FIG. 7b, the load line labeled 1 in the graph is the load line when an initial bias signal and supply voltage is input into the PA 22. The load line labeled 2 shows how the load line changes when the bias signal increases, due to an increase in the envelope of the RF signal, which causes the gradient of the load line to become steeper (as described in FIG. 3). The load line labeled 4 shows how the load line 1 changes when the supply voltage increases, due to an increase in the envelope of the RF signal. The increase in the supply voltage shifts the load line upwards on the graph, whilst maintaining the same gradient. Therefore the power amplifier is supplied with a higher power only when needed for a larger input signal, thus improving efficiency. The load line labelled 3 shows how the load line changes if the bias signal was decreased at the same supply voltage as load line 4.

In general, the envelope modulated bias signal and envelope modulated supply voltage dynamically together modulate the load line to increase the efficiency of the power amplifier 22.

Returning to FIG. 7a, a time calibration can be performed, as discussed previously, by methods and configurations as described in U.S. Pat. No. 11,165,514 B2, or as described above in relation to FIGS. 5b and 5c, or a combination thereof.

Further, the two paths (i.e. envelope signal into the bias signal and envelope signal into the supply voltage) can have different bandwidths based on Rx noise (noise in the adjacent bands used by other UE) and/or complexity of the delay calibration control.

As before, in FIG. 7a various different classes of power amplifier may be used. In the case of a class E PA, the class E output impedance matching circuit 300 of FIG. 2b may be used.

### Power Amplifier Control Circuitry

FIG. 8 shows an amplification circuit 800 in an exemplary embodiment of the present disclosure. The amplification circuit 800 is an example of a bias-based load modulation power amplifier system, such as the system 20 of FIG. 2a.

The amplification circuit 800 includes a power amplifier 22 (also referred to as a PA stage), an input impedance matching circuit 24, a capacitor 26, and an output impedance matching circuit 32. These components are equivalent to the similarly numbered components from FIG. 2a. The class E output impedance matching circuit 300 of FIG. 2b may be used as the output impedance matching circuit 32 in some embodiments.

In the embodiment of FIG. 8, the PA stage 22 includes a first amplifying transistor 802 and a second amplifying transistor 804. In the present embodiment, the first and second amplifying transistors 802,804 are bipolar transistors, however other types of transistor may be used. The base terminals of the transistors 802,804 are connected together via an inductor 806. The emitter terminals of the transistors 802,804 are both connected to ground. The input impedance matching circuit 24 receives an input RF signal (RF_in), and its output is connected is connected to the base of the second amplifying transistor 804 via capacitor 26. The collector terminal of the second amplifying transistor 804 is connected to a constant supply voltage Vdd via the output impedance matching circuit 32, which outputs an amplified RF signal (RF_out).

The amplification circuit 800 of FIG. 8 further includes a biasing circuit 810. The biasing circuit 810 includes a first resistor 812, a second resistor 814 and a differential amplifier 816 (also referred to as a servo amplifier herein). The biasing circuit receives the constant supply voltage Vdd, which is input into a non-inverting input of the amplifier 816 via the first resistor 812, and is input into an inverting input of the amplifier 816 via the second resistor 814.

Further, a current signal (Iref) is input into the non-inverting input of the amplifier 816. The current signal Iref is produced from a constant current signal (Ibias), and an envelope current signal (Itrck) which is based on the envelope of the input RF signal, RF_in. Iref may be the sum of Ibias and Itrck in some embodiments. In this way, an envelope signal produced from the RF_in signal is input into the non-inverting input of the differential amplifier 816.

The collector terminal of the first amplifying transistor 802 is connected to the inverting input of the amplifier 816. A current feedback signal (Ibias_PA) therefore passes between the inverting input of the amplifier 816 in the biasing circuit 810 and the first amplifying transistor 802 of the PA 22. In some embodiments, the current signal Ibias_PA may be calculated using the following formula:

$$Ibias\_PA = Iref ( R 1 / R 2 )$$

where R1 is the resistance of the first resistor 812 and R2 is the resistance of the second resistor 814.

The differential amplifier 816 of the biasing circuit 810 then outputs the bias signal (Vbias_PA) to the power amplifier 22. The output impedance of the differential amplifier 816 (and the biasing circuit 810) is marked on FIG. 8 as Rout. Specifically, the bias signal Vbias_PA is output by the differential amplifier 816 and input into the base terminal of the first amplifying transistor 802. A capacitor 818 is connected between the base of the first amplifying transistor 802 and ground.

In this way, the biasing circuit 810 is configured to receive an envelope signal (i.e. Itrck) produced from the RF_in signal and input a bias signal (i.e. Vbias_PA) into the power amplifier 22, specifically the base of the first amplifying transistor 802. As described in relation to FIGS. 2a and 4, the bias signal Vbias_PA produced by the biasing circuit 810 varies based on the envelope signal such that the bias signal dynamically modulates an output impedance of the power amplifier 22 based on the envelope signal, to perform bias-based dynamic load modulation.

In some embodiments, the bias signal (Vbias_PA) and envelope signal (Itrck) may be time calibrated, for example using the methods described in FIGS. 5b and 5c above, such that the bias signal is time calibrated to within 3 ns or less of the envelope of the input RF signal (RF_in). In this way, the amplification circuit 800 may perform the methods of FIGS. 4 and 6 in various embodiments, particularly for input RF signals with high modulation bandwidths.

FIG. 9 shows an amplification circuit 900 in another exemplary embodiment of the present disclosure. The amplification circuit 900 is another example of a bias-based load modulation power amplifier system, such as the system 20 of FIG. 2a.

The amplification circuit 900 of FIG. 9 is identical to the amplification circuit 800 of FIG. 8, except for the configuration of the PA stage 22. Namely, the PA 22 in FIG. 9 incudes a first amplifying transistor 902, a second amplifying transistor 904, a third amplifying transistor 906, and a fourth amplifying transistor 908. The base terminals of the first and second transistors 902,904 are connected together via an inductor 910. The emitter terminals of the first and second transistors 902,904 are both connected to ground. The output of the input impedance matching circuit 24 is input into the base terminal of the second amplifying transistor 904 via the capacitor 26. The base terminal of the first amplifying transistor 902 receives the bias signal, Vbias_PA, from the biasing circuit 810.

The amplification circuit 900 of FIG. 9 differs in that the transistors are cascode connected, with the collector terminal of the first amplifying transistor 902 is connected to the emitter of the third amplifying transistor 906, and the collector terminal of the second amplifying transistor 904 is connected to the emitter of the fourth amplifying transistor 908. The base terminals of the third and fourth amplifying transistors 906,908 are connected together via the resistor 912. The collector terminal of the fourth amplifying transistor 908 is connected to a constant supply voltage Vdd via the output impedance matching circuit 32. The collector terminal of the third amplifying transistor 906 is connected to the inverting input of the amplifier 816, to pass a current signal (Ibias_PA) between the inverting input of the amplifier 816 and the third amplifying transistor 906. The base of the third amplifying transistor 906 receives a cascode voltage signal (Vcsc), which is a constant voltage signal in the present embodiment. A capacitor 914 is connected between the base of the third amplifying transistor 906 and ground.

The amplification circuit 900 of FIG. 9 performs bias-based load modulation in the same way as the amplification circuit 800 of FIG. 8. Again, although described using bipolar transistors, any type of transistor may be used in the present disclosure, such as MOSFETs or the like.

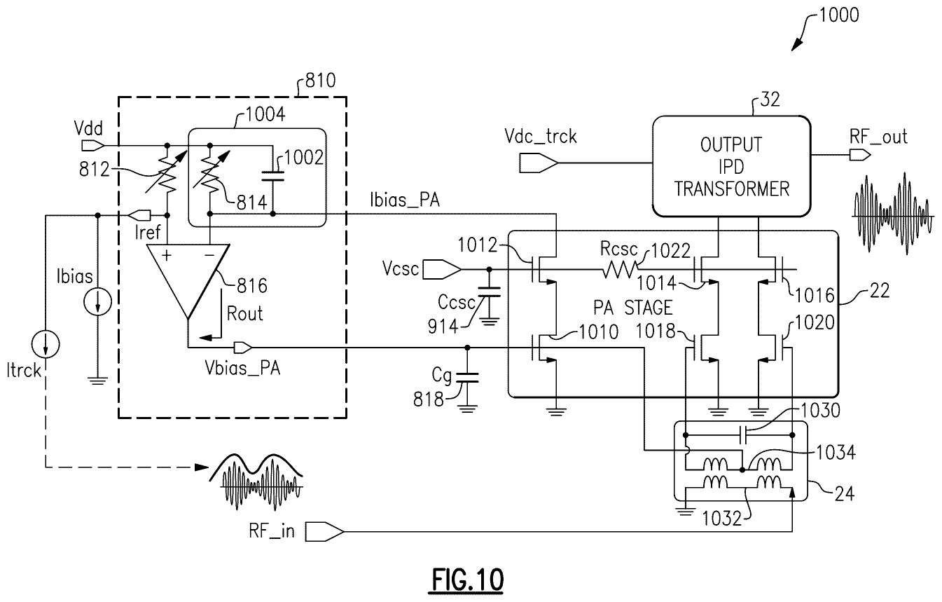

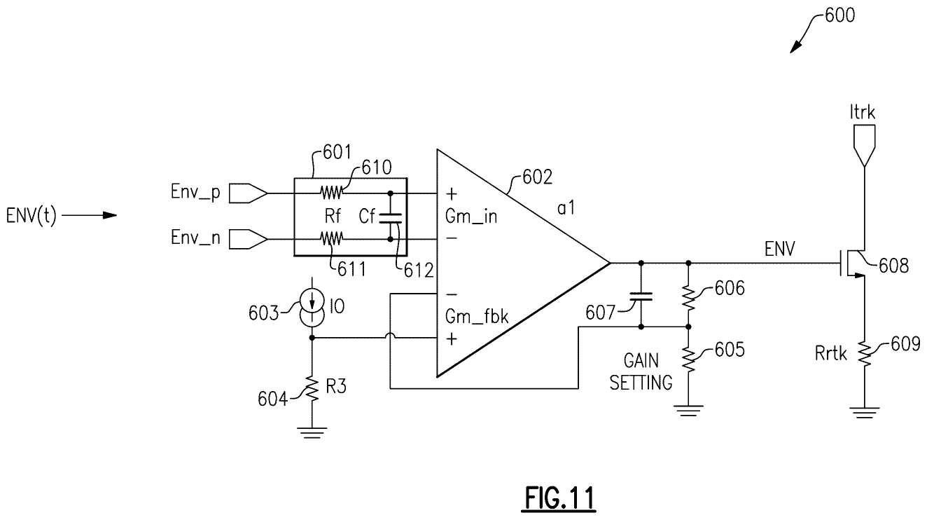

FIG. 10 shows an amplification circuit 1000 in another exemplary embodiment of the present disclosure. The amplification circuit 1000 is another example of a bias-based load modulation power amplifier system. However, unlike the circuits of FIGS. 8 and 9, which use a constant supply voltage for the PA, the amplification circuit 1000 of FIG. 10 is a two-way ET modulator such as the system 70 of FIG. 7a. In other words, the amplification circuit 1000 of FIG. 10 performs dynamic supply modulation as well as bias-based load modulation.

The amplification circuit 1000 is the same as the circuits 800 and 900 of FIGS. 8 and 9, except for the following differences. Firstly, the biasing circuit 810 further includes an optional filter capacitor 1002 connected in parallel with the second resistor 814, between the constant voltage Vdd and the inverting input of the differential amplifier 816. Together the second resistor 814 and filter capacitor 1002 form the filter circuit 1004. This filter circuit 1004 may also be used in the circuits 800 and 900 of FIGS. 8 and 9 in some embodiments.

Secondly, in the amplification circuit 1000 the PA 22 receives a supply voltage to the PA 22 that varies based on the envelope of the input RF signal, RF_in. Specifically, the envelope-based supply voltage Vdc_track is supplied to the PA 22 via the output impedance matching circuit 32 in the amplification circuit 1000. In embodiments of the disclosure, the output impedance matching circuit 32 may be an integrated passive device (IPD) transformer. The envelope-based supply voltage Vdc_track may be produced by various envelope tracking (ET) configurations, such as the envelope tracking (ET) driver 72 of FIG. 7a.

Lastly, the configuration of the PA stage 22 in the amplification circuit 1000 of FIG. 10 differs from that of FIGS. 8 and 9. The PA stage 22 in the amplification circuit 1000 includes a first amplifying transistor 1010, a second amplifying transistor 1012, a third amplifying transistor 1014, a fourth amplifying transistor 1016, a fifth amplifying transistor 1018, and a sixth amplifying transistor 1020. In the embodiment of FIG. 10 MOSFETs are used as the amplifying transistors, however any type of transistor may be used in general.

The gate terminal of the first amplifying transistor 1010 is connected to the output of the biasing circuit (the bias signal Vbias_PA). The source terminal of the first amplifying transistor 1010 is connected to ground. The first amplifying transistor 1010 is cascode connected to the second transistor 1012, with the drain terminal of the first amplifying transistor 1010 connected to the source terminal of the second amplifying transistor 1012. The gate terminal of the second transistor receives the constant cascode voltage Vesc. The drain terminal of the second amplifying transistor 1012 is connected to the inverting input of the amplifier 816, to pass a current signal (Ibias_PA) between the inverting input of the amplifier 816 and the second amplifying transistor 1012.

The gate terminal of the second amplifying transistor 1012 is connected to the gate terminals of the third amplifying transistor 1014 and fourth amplifying transistor 1016 via a resistor 1022. The drain terminals of the third and fourth amplifying transistors 1014,1016 are connected to the envelope-based supply voltage Vdc_track via output impedance matching circuit 32. The source terminals of the third and fourth amplifying transistors 1014,1016 are cascode connected to the drain terminals of the fifth amplifying transistor 1018 and the sixth amplifying transistor 1020 respectively.

The drain terminals of the fifth and sixth amplifying transistors 1018,1020 are both connected to ground. The gate terminals of the fifth and sixth amplifying transistors 1018,1020 are both connected to the gate terminal of the first amplifying transistor 1010 via the input impedance matching circuit 24. Specifically, in the present embodiment, the input impedance matching circuit 24 includes a first capacitor 1030, a first coil 1032 and a second coil 1034. The first coil 1032 is coupled to the second coil 1034 as a transformer. The first coil 1032 receives the input RF signal RF_in and transfers this to the second coil 1034 via induction. The second coil 1034 is connected in series between the gate terminals of the fifth amplifying transistor 1018 and the sixth amplifying transistor 1020, and the gate terminal of the first amplifying transistor 1010 is connected to a midpoint of the second coil 1034. The first capacitor 1030 is connected between the gate terminals of the fifth amplifying transistor 1018 and the sixth amplifying transistor 1020, in parallel to the second coil 1034.

As described in relation to FIG. 7a, in the amplification circuit 1000 of FIG. 10 the bias signal (Vbias_PA) produced by the biasing circuit 810 varies based on the envelope signal such that the bias signal dynamically modulates an output impedance of the power amplifier 22 based on the envelope signal, to perform bias-based dynamic load modulation. Further, the supply voltage Vdc_trck is dynamically modulated based on the envelope signal, to perform envelope tracking dynamic load modulation. A very high efficiency is therefore achieved by the PA stage 22 when amplifying the input RF signal, RF_in.

In some embodiments, both the bias signal (Vbias_PA)/envelope signal (Itrck) and/or the envelope-based voltage signal (Vdc_trck) may be time calibrated. For example the methods described in FIGS. 5b and 5c above may be used to time calibrate these signals to within 3 ns or less of the envelope of the input RF signal (RF_in). In this way, the amplification circuit 800 may perform the methods of FIGS. 4 and 6, particularly for input RF signals with high modulation bandwidths.

Each of the amplification circuits 800,900, 1000 of FIGS. 8 to 10 advantageously has a low output impedance Rout for the biasing circuit 810. This further improves the efficiency of the power amplification circuit, e.g. by preventing power wastage through heat dissipation. Further, in the case of mmWave signals a low impedance is beneficial, as an impedance mismatch into a driver can create nonlinearity in the power amplifier.

FIG. 11 shows an exemplary circuit 600 for generation of the envelope current signal (Itrck) of FIGS. 8 to 10 according to some embodiments of the present disclosure. The circuit 600 may be referred to as an envelope signal interface 600, or a differential envelope amplifier 600. Although one example of the envelope signal interface 600 is shown, the envelope signal interface 600 of FIG. 11 can be implemented in other ways.

The envelope signal interface 600 includes a differential input envelope filter 601, a dual input differential amplifier 602, a current source 603, a load resistor 604, a first feedback resistor 605, a second feedback resistor 606, a feedback capacitor 607, an output transistor 608 and an output resistor 609. Additionally, the differential input envelope filter 601 includes a first input resistor 610, a second input resistor 611, and an input capacitor 612.

The differential input envelope filter 601 filters a differential input signal (Env_p, Env_n) to generate a differential envelope signal that is provided to a first differential input of the dual input differential amplifier 602. The dual input differential amplifier 602 further includes an output that generates an envelope signal ENV, and a feedback loop from the output to a second differential input. Put another way, the current source 603, load resistor 604, first feedback resistor 605, second feedback resistor 606, and feedback capacitor 607 together form a common mode feedback circuit. This common mode feedback circuit inputs a differential compensation signal into the second differential input of the dual input differential amplifier 602, that compensates for an error arising from a common mode voltage of the differential envelope Env(t) signal Env_p, Env_n. In certain implementations the current source 603 is controllable (for instance, variable and/or programmable) to control a common mode setting for providing common mode feedback.

The differential input envelope filter 601 can advantageously receive a differential envelope signal in a sigma delta format. Thus, the differential input signal (Env_p, Env_n) can carry a sequence of pulses. Additionally, the resulting envelope signal ENV can be filtered to recover the envelope in an analog format, or processed to generate a digital representation of the envelope.

Accordingly, the envelope signal interface 600 provides flexibility in generating an envelope signal in analog or digital format as desired.

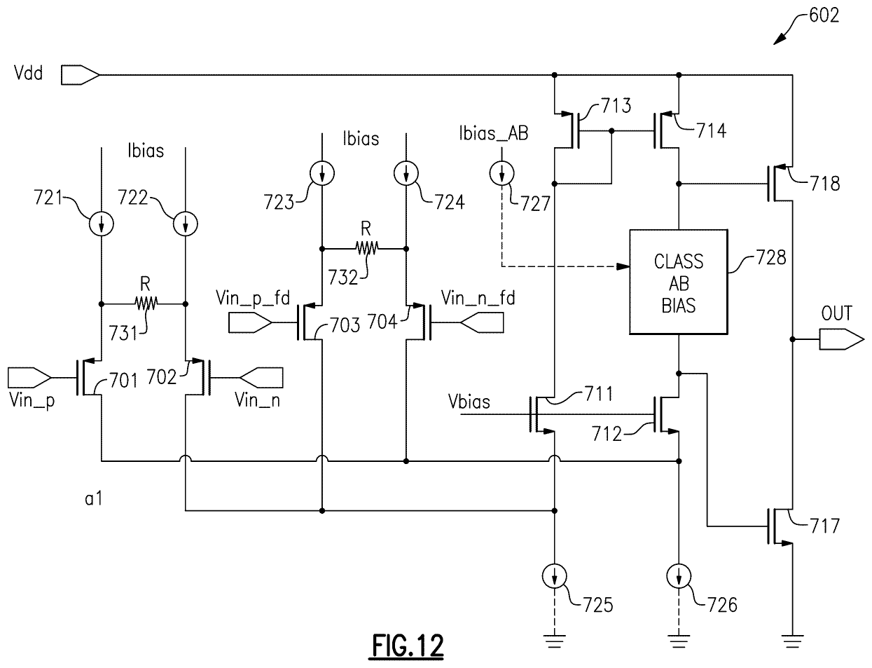

FIG. 12 shows one exemplary embodiment of circuitry for the dual input differential amplifier 602 of FIG. 11. Although one example of a suitable circuit is shown, the dual input differential amplifier 602 can include amplification circuitry implemented in a wide variety of ways.

As shown in FIG. 12, the dual input differential amplifier 602 includes a first pair of p-type field effect transistors (PFETs) 701,702 for amplifying a first differential input Vin_p,Vin_n. The first pair of PFETs 701,702 is biased by a first pair of current sources 721,722 (each providing a current Ibias, in this example), and includes a first resistor 731 of resistance R for coupling the source of the PFET 701 to the source of the PFET 702. The dual input differential amplifier 602 further includes a second pair of PFETs 703,704 for amplifying a second differential input Vin_p_fd, Vin_n_fd, corresponding to a differential common mode compensation signal. The second pair of PFETs 703,704 is biased by a second pair of current sources 723,724 (also providing a current Ibias, in this example), and includes a second resistor 732 (also of resistance R, in this example) for coupling the source of the PFET 703 to the source of the PFET 704.

Currents from the first pair of PFETs 701,702 and the second pair of PFETs 703,704 are combined using folded cascode circuitry that includes current sources 725,726, n-type field effect transistors (NFETs) 711,712, and PFETs 713,714. In this example, the gates of NFETs 711,712 are controlled by a bias voltage Vbias.

The dual input differential amplifier 602 further includes a push-pull output stage including NFET 717, PFET 718, a current source 727, and a class AB bias circuit 728. As shown in FIG. 12, the current source 727 provides a current Ibias_AB to the class AB bias circuit 728, which biases the NFET 717 and PFET 718 to provide enhanced bandwidth. The dual input differential amplifier 602 receives a supply voltage, Vdd (not shown previously in FIG. 11), at PFETs 713,714 and PFET 718.

FIG. 13 shows one exemplary embodiment of the biasing circuit 810 of FIGS. 8 to 10, including circuitry for the differential amplifier 816 (servo amplifier). Although one example of a suitable circuit is shown, the differential amplifier 816 can include amplification circuitry implemented in a wide variety of ways. For example, the circuit of FIG. 13 is described using field-effect transistors (FETs), however any type of transistors may be used.

As shown in FIG. 13, the differential amplifier 816 includes a first p-type field effect transistors (PFET) 852, a second PFET 854, a third PFET 856, an n-type field effect transistor (NFET) 858, a first current source 862 producing a bias current signal Ibias1, a second current source 864 producing a bias current signal Ibias2, a resistor 866, and a third current source 868 producing a bias current signal Ibias4.

The source terminals of the first PFET 852 and second PFET 854 form the non-inverting and inverting input respectively of the differential amplifier 816. In other words, the source terminal of the first PFET 852 is connected to the first resistor 812 in the biasing circuit 810 of FIGS. 8 to 10, and the source terminal of the second PFET 854 is connected to the second resistor 814 in the biasing circuit 810 of FIGS. 8 to 10. Therefore the signal Iref is input into the source terminal of the first PFET 852, and the signal Ibias_PA is input into the source terminal of the second PFET 854. The drain terminals of the first and second PFETs 852,854 are connected to the first current source 862 and the third current source 868 respectively. The gate terminals of the first and second PFETs 852,854 are connected together. Further, the gate terminal of the second PFET 854 is connected to the drain terminal of the second PFET 854.

The drain terminal of the first PFET 852 is connected to the gate terminal of the third PFET 856. The source terminal of the third PFET 856 receives the supply voltage, Vdd, and the drain terminal of the third PFET 856 is connected to the second current source 864. Further, the drain terminal of the third PFET 856 is connected to the gate terminal of the NFET 858. The drain terminal of the NFET 858 also receives the supply voltage, Vdd, and the source terminal of the NFET 858 is connected to ground via the resistor 866. The source terminal of the NFET 858 forms the output of the differential amplifier 816, such that the bias signal Vbias_PA is output at the source terminal of the NFET 858.

The differential amplifier 816 of FIG. 13 therefore receives the current signal Iref (produced from the constant current signal Ibias and the envelope current signal Itrck), and receives current signal Ibias_PA, and uses these to produce the bias signal Vbias_PA to perform

$$Ibias\_PA = Iref ( R 1 / R 2 )$$

bias-based load modulation. As mentioned, the current signal Ibias_PA may be calculated using the following formula in some embodiments:

The output impedance of the differential amplifier 816 (and the hence the biasing circuit 810) is marked on FIG. 13 as Rout. As mentioned above, the biasing circuit 810 advantageously has a low output impedance over a broad frequency range.

In more detail, at low frequencies, e.g. at the baseband frequency, the output impedance is low. As the frequency increases, the differential amplifier 816 has gain and the output impedance Rout increases whilst following the formula:

$$Rout = \frac{{R}_{o}}{1 + β {A}_{o}}$$

where R_{O} is the output impedance seen by the differential amplifier 816 without feedback, β is a feedback coefficient, and A_{O} is an open loop gain at DC. At even higher frequencies, the output impedance begins to drop due to the output capacitor 818 which decreases the output impedance at higher frequencies. The peak output impedance is at the transition of these two regions, i.e. the region set by the differential amplifier 816 and the region set by the capacitor 818. At this peak, the output impedance Rout is set by the resistor 866, for example proportional to the resistance of the resistor. The peak output impedance is therefore reduced in the present embodiment by increasing the current through NFET 858, which is in a source follower configuration.

In some embodiments, the amplifier systems and circuits described above can be implemented on one or more semiconductor die, and such die can be included in a packaged module such as a power amplifier module (PAM) or a front-end module (FEM). Such a packaged module is typically mounted on a circuit board associated with, for example, a portable wireless device.

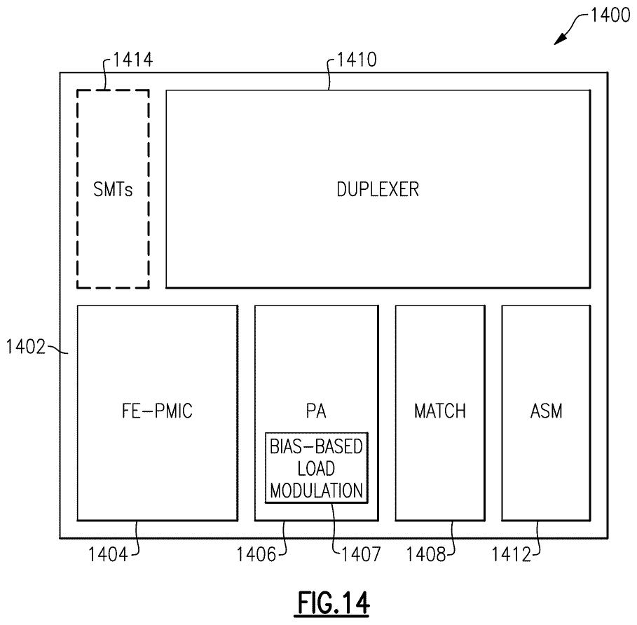

FIG. 14 shows that in some embodiments, some or all of power amplification systems (e.g., those shown in FIGS. 2a, 7a, and 8 to 13) can be implemented, wholly or partially, in a module. Such a module can be, for example, a front-end module (FEM). In the example of FIG. 14, a module 1400 can include a packaging substrate 1402, and a number of components can be mounted on such a packaging substrate. For example, an FE-PMIC (Front-end Power Management Integrated Circuit) component 1404, a power amplifier assembly 1406, a match component 1408, and a duplexer assembly 1410 can be mounted and/or implemented on and/or within the packaging substrate 1402. The power amplifier assembly 1406 can perform bias-based load modulation through bias-based load modulation configurations 1407 such as those described above with respect to FIGS. 2a, 7a, and 8 to 13. Other components such as a number of SMT (surface-mount technology) devices 1414 and an antenna switch module (ASM) 1412 can also be mounted on the packaging substrate 1402. Although all of the various components are depicted as being laid out on the packaging substrate 1402, it will be understood that some component(s) can be implemented over other component(s).

In some implementations, a device and/or a circuit having one or more features described herein can be included in an RF device such as a wireless device. Such a device and/or a circuit can be implemented directly in the wireless device, in a modular form as described herein, or in some combination thereof. In some embodiments, such a wireless device can include, for example, a cellular phone, a smart-phone, a hand-held wireless device with or without phone functionality, a wireless tablet, etc.

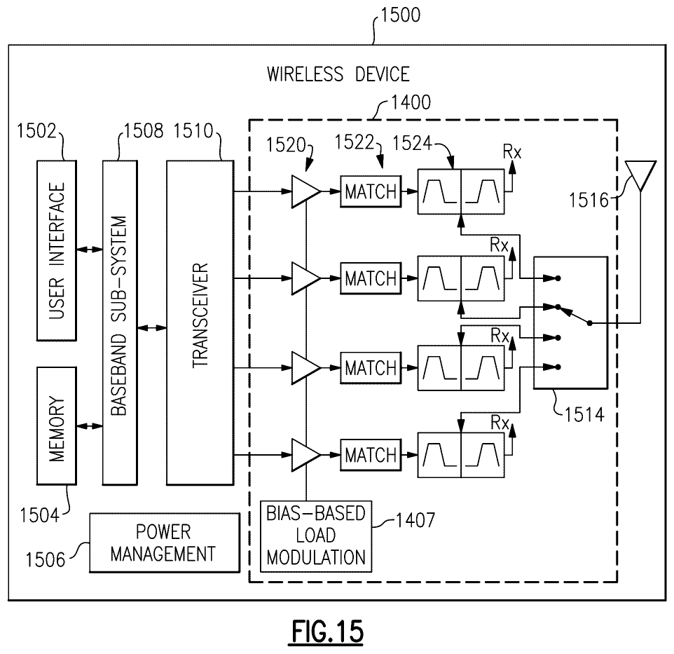

FIG. 15 depicts an example wireless device 1500 having one or more advantageous features described herein. In the context of a module having one or more features as described herein, such a module can be generally depicted by a dashed box 1400, and can be implemented as, for example, a front-end module (FEM).

Referring to FIG. 15, power amplifiers (PAs) 1520 can receive their respective RF signals from a transceiver 1510 that can be configured and operated in known manners to generate RF signals to be amplified and transmitted, and to process received signals. The transceiver 1510 is shown to interact with a baseband sub-system 1508 that is configured to provide conversion between data and/or voice signals suitable for a user and RF signals suitable for the transceiver 1510. The transceiver 1510 can also be in communication with a power management component 1506 that is configured to manage power for the operation of the wireless device 1500. Such power management can also control operations of the baseband sub-system 1508 and the module 1400.

The baseband sub-system 1508 is shown to be connected to a user interface 1502 to facilitate various input and output of voice and/or data provided to and received from the user. The baseband sub-system 1508 can also be connected to a memory 1504 that is configured to store data and/or instructions to facilitate the operation of the wireless device, and/or to provide storage of information for the user.

In the example wireless device 1500, outputs of the PAs 1520 are shown to be matched (via respective match circuits 1522) and routed to their respective duplexers 1524. Such amplified and filtered signals can be routed to an antenna 1516 through an antenna switch 1514 for transmission. In some embodiments, the duplexers 1524 can allow transmit and receive operations to be performed simultaneously using a common antenna (e.g., 1516). In FIG. 15, received signals are shown to be routed to “Rx” paths (not shown) that can include, for example, a low-noise amplifier (LNA).

A number of other wireless device configurations can utilize one or more features described herein. For example, a wireless device does not need to be a multi-band device. In another example, a wireless device can include additional antennas such as diversity antenna, and additional connectivity features such as Wi-Fi, Bluetooth, and GPS.

In certain implementations, multiple antennas may be used to support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

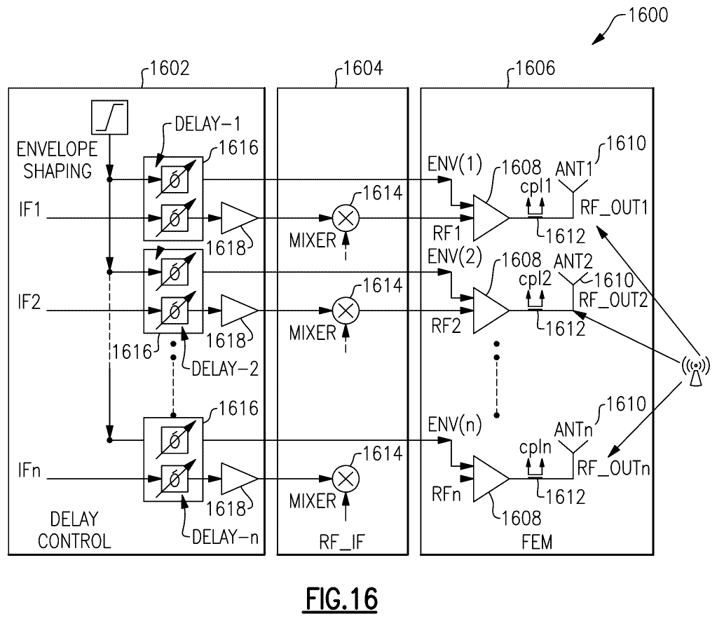

FIG. 16 shows a MIMO system 1600 that includes power amplifier circuits and systems according to embodiments of the present disclosure. The MIMO system 1600 includes a delay control module 1602, an RF module 1604 and a front-end module (FEM) 1606.

In the present embodiment, the RF module 1604 and FEM 1606 use the same configurations as described for modules 502 and 503 in FIG. 5c. However, the MIMO system 1600 uses n channels rather than the single channel described in FIG. 5c.

Specifically, the FEM 1606 includes a plurality of PAs 1608, each having a respective antenna 1610 and a respective directional coupler 1612. Each PA 1608 of the FEM 1606 receives a respective RF signal RF1, RF2, . . . . RFn from a respective I/Q up-conversion mixer 1614 in the RF module 1604. The various other components of modules 502 and 503 have been omitted in FIG. 16 for simplicity.

Further, the delay control module 1602 receives a plurality of intermediate RF signals IF1, IF2, . . . . IFn along with the corresponding envelope signals for each of the RF signals, IFn. The delay control module 1602 includes a delay circuit 1616 and an amplifier 1618 for each of the RF signals, IFn. Each delay circuit 1616 outputs a time calibrated envelope signal Env(1), Env(2), . . . . Env(n) to a respective one of the plurality of PAs 1608. The envelope signals Env(n) are each input into the bias of the respective PA, to perform bias-based DLM, as described in FIGS. 2a and 7a for example. Further, each RF signal IFn is sent from the respective delay circuit 1616, via the respective amplifier 1618 and mixer 1614, to the respective PA 1608 as a time calibrated RF signal RF1, RF2, . . . . RFn. The time calibration may be performed by the delay circuits 1616 using the same methods as described previously, e.g. an observation receiver (not shown) in combination with the directional couplers 1612 and observation mixers 1614. In some embodiments, a single observation receiver may be used for the multiple channels. In other words, the system of FIG. 5c may be used, but with multiple power amplifiers in the FEM, each PA being attached to one of a plurality of antennas.

The MIMO system 1600 of FIG. 16 has a number of benefits. Firstly, the time calibration is done in digital domain using the observation receiver, which results in a simplified MIMO system due to the simplified calibration. This is made possible by the bias-based load modulation methods and systems described in the previous embodiments. Moreover, in order to beamform the n beams there is the need to phase delay the signals for different channels. In the MIMO system 1600 of FIG. 16 this can be done without affecting the delay alignment required for the envelope-based load modulation. In general, any of the various methods and embodiments described in FIGS. 2a to 13 may be used in the MIMO system 1600.

### Terminology

Having described above several aspects of at least one embodiment, it is to be appreciated various alterations, modifications, and improvements will readily occur to those skilled in the art. Such alterations, modifications, and improvements are intended to be part of this disclosure and are intended to be within the scope of the disclosure. Accordingly, the foregoing description and drawings are by way of example only, and the scope of the disclosure should be determined from proper construction of the appended claims, and their equivalents.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes example embodiments, the teachings described herein can be applied to a variety of structures. Any of the principles and advantages discussed herein can be implemented in association with RF circuits configured to process signals having a frequency in a range from about 30 kHz to 300 GHz, such as in a frequency range from about 450 MHz to 8.5 GHz. Acoustic wave filters disclosed herein can filter RF signals at frequencies up to and including millimeter wave frequencies.

Aspects of this disclosure can be implemented in various electronic devices. Examples of the electronic devices can include, but are not limited to, consumer electronic products, parts of the consumer electronic products such as packaged radio frequency modules, radio frequency filter die, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a robot such as an industrial robot, an Internet of things device, a stereo system, a digital music player, a radio, a camera such as a digital camera, a portable memory chip, a home appliance such as a washer or a dryer, a peripheral device, a wrist watch, a clock, etc. Further, the electronic devices can include unfinished products.

Unless the context indicates otherwise, throughout the description and the claims, the words “comprise,” “comprising,” “include,” “including” and the like are to generally be construed in an inclusive sense, as opposed to an exclusive or exhaustive sense; that is to say, in the sense of “including, but not limited to.” Conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively.

While certain embodiments have been described, these embodiments have been presented by way of example only, and are not intended to limit the scope of the disclosure. Indeed, the novel resonators, filters, multiplexer, devices, modules, wireless communication devices, apparatus, methods, and systems described herein may be embodied in a variety of other forms. Furthermore, various omissions, substitutions and changes in the form of the resonators, filters, multiplexer, devices, modules, wireless communication devices, apparatus, methods, and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and/or acts of the various embodiments described above can be combined to provide further embodiments. The accompanying claims and their equivalents are intended to cover such forms or modifications as would fall within the scope and spirit of the disclosure.

What is claimed is:

1. An amplification circuit comprising:
a power amplifier stage of a power amplifier configured to receive a supply voltage and an RF signal to be amplified;
a bias circuit configured to receive an envelope signal produced from the RF signal and input a bias signal into the power amplifier, said bias signal varying based on the envelope signal such that the bias signal dynamically modulates an output impedance of the power amplifier based on the envelope signal; and
an output stage configured to output an amplified RF signal generated by the power amplifier.

2. The amplification circuit of claim 1 wherein the envelope signal is a time calibrated envelope signal.

3. The amplification circuit of claim 2 wherein the envelope signal is time calibrated such that the bias signal that is input into the power amplifier is time calibrated to within 3 ns of an envelope of the RF signal.

4. The amplification circuit of claim 3 wherein the envelope signal is time calibrated such that the bias signal that is input into the power amplifier is time calibrated to within 0.5 ns of the envelope of the RF signal.

5. The amplification circuit of claim 1 wherein the envelope signal is a current signal that varies based on an envelope of the RF signal.

6. The amplification circuit of claim 1 wherein the bias circuit is configured to receive a constant bias signal.

7. The amplification circuit of claim 1 wherein the bias circuit comprises a differential amplifier.

8. The amplification circuit of claim 7 wherein a first input of the differential amplifier receives the envelope signal.

9. The amplification circuit of claim 8 wherein a second input of the differential amplifier is connected to a drain or collector terminal of a transistor in the power amplifier stage.

10. The amplification circuit of claim 9 wherein an output of the differential amplifier is connected to a gate or base terminal of a transistor in the power amplifier stage.

11. The amplification circuit of claim 1 wherein the supply voltage is a constant voltage signal.

12. The amplification circuit of claim 1 further comprising an envelope tracking driver configured to receive the envelope signal produced from the RF signal and to vary the supply voltage based on the envelope signal.

13. The amplification circuit of claim 12 wherein the envelope signal is a time calibrated envelope signal.

14. The amplification circuit of claim 1 wherein an increase in the envelope signal produced from the RF signal causes an increase in the bias signal, and the increase in the bias signal causes a decrease in the output impedance of the power amplifier.

15. The amplification circuit of claim 1 wherein an increase in the envelope signal produced from the RF signal causes an increase in the bias signal, and the increase in the bias signal causes an increase in a load line of the power amplifier.

16. The amplification circuit of claim 1 further comprising an input stage configured to input the RF signal to be amplified into the power amplifier.

17. The amplification circuit of claim 1 wherein the RF signal has a modulation bandwidth greater than 60 MHz.

18. The amplification circuit of claim 1 wherein the RF signal is a 5G mmWave signal.

19. An amplification method comprising:
receiving, by a power amplifier stage of a power amplifier, a supply voltage and an RF signal to be amplified;
inputting a bias signal into the power amplifier, said bias signal varying based on an envelope signal produced from the RF signal such that the bias signal dynamically modulates an output impedance of the power amplifier based on the envelope signal; and
outputting an amplified RF signal generated by the power amplifier.

20. A wireless device comprising:
a transceiver configured to generate an RF signal;
a front-end module (FEM) in communication with the transceiver, the FEM including a packaging substrate configured to receive a plurality of components, and an amplification circuit including a power amplifier stage of a power amplifier configured to receive a supply voltage and an RF signal to be amplified, a biasing circuit configured to input a bias signal into the power amplifier, said bias signal varying based on an envelope signal produced from the RF signal such that the bias signal dynamically modulates an output impedance of the power amplifier based on the envelope signal, and an output stage configured to output an amplified RF signal generated by the power amplifier; and
an antenna in communication with the FEM, the antenna configured to transit the amplified RF signal received from the amplification circuit.
